(19) United States
(12) Patent Application Publication
(10) Pub. No.: US 2015/0015189 A1
(43) Pub. Date: Jan. 15, 2015

(54) PORTABLE POWER SOURCE PROVIDING SUPPORT BY NOTCH

(71) Applicants: SHENZHEN FUTAIHONG PRECISION INDUSTRY CO., LTD., Shenzhen (CN); FIH (HONG KONG) LIMITED, Kowloon (HK)

(72) Inventor: LEI HUANG, Shenzhen (CN)

(21) Appl. No.: 14/317,641

(22) Filed: Jun. 27, 2014

(30) Foreign Application Priority Data
Jul. 2, 2013 (CN) 2013102735173

(51) Int. Cl. H05K 5/02; H02J 7/00; H05K 5/00

(52) U.S. Cl. CPC H05K 5/0217; H05K 5/0086; H02J 7/0042
USPC 320/107; 361/728

(57) ABSTRACT

A portable power source includes a housing and a support member. The housing has a power supply module. The support member includes a main body detachably mounted in the housing and the housing has the appearance of being notched when the support member is inserted therein. A notch is defined on the main body to provide support for the electronic device for viewing or other purposes.

### FIELD

The subject matter herein generally relates to a portable power source.

### BACKGROUND

Portable power sources are often used to charge portable electronic devices, such as mobile phones or tablet computers. If the portable electronic device is supported, it can be viewed and used during the charging.

### BRIEF DESCRIPTION OF THE DRAWINGS

Implementations of the present technology will now be described, by way of example only, with reference to the attached figures.

FIG. 1 is an exploded, isometric view of an embodiment of a portable power source.

FIG. 2 is similar to FIG. 1, but shown from another angle.

FIG. 3 is an isometric view of a support member of the portable power source.

FIG. 4 is an assembled view of the portable power source.

FIG. 5 is an isometric view of the portable power source of FIG. 4 used for supporting an electronic device.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” when utilized, means “including, but not necessarily limited to”; it specifically indicates open-ended inclusion or membership in the so-described combination, group, series and the like.

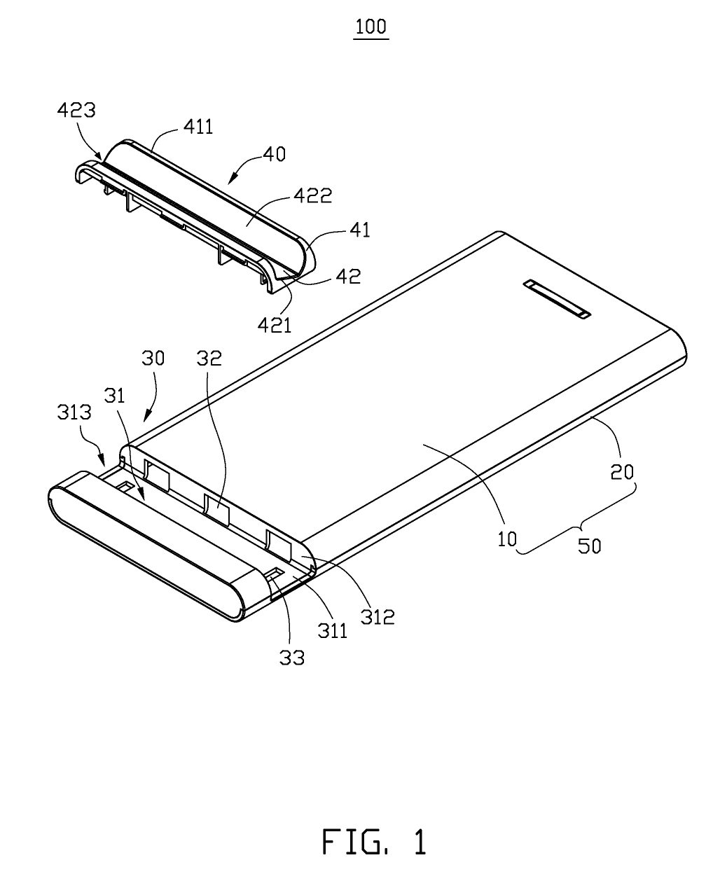

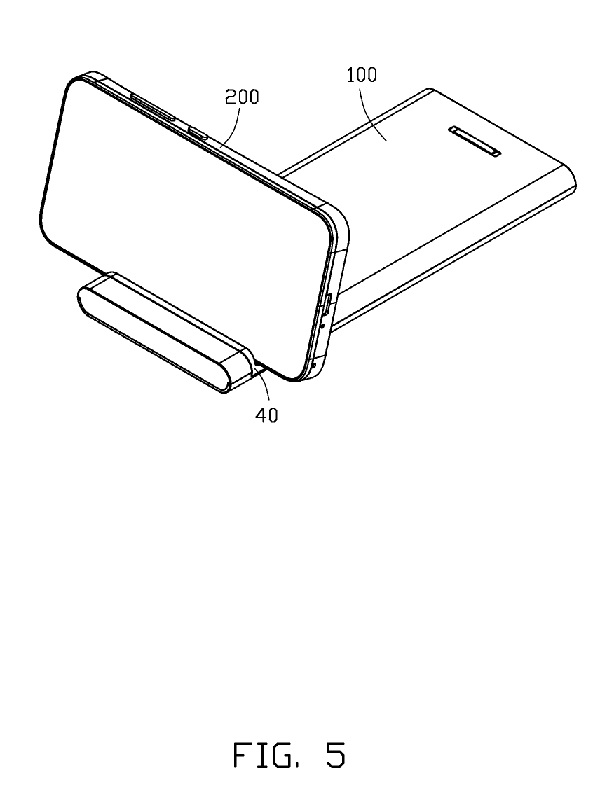

FIG. 1 illustrates a portable power source 100 for providing power to an electronic device 200 (also see FIG. 5), such as a mobile phone or a tablet computer. The portable power source 100 includes a housing 50 and a support member 40. The support member 40 includes a main body 41 detachably mounted in the housing 50. A notch 42 is defined on the main body 41 and configured to latch and support the electronic device 200.

The main body 41 includes an exterior surface 411 and an interior surface 412 opposite to the exterior surface 411. The notch 42 is recessed from the exterior surface 411 toward the interior surface 412. As illustrated, the notch 42 includes an inclined surface 421, two opposite sidewalls 422 extending from the inclined surface 421, and two opposite end walls defining two first cutouts 423. The inclined surface 421 is configured to support the electronic device 200 in a desired angle.

The housing 50 includes a first housing 10 and a second housing 20. The first housing 10 can be assembled on the second housing 20 by a latch or other mechanism. A receiving portion 30 is formed on the housing 50 and defines a receiving slot 31 configured to receive the support member 40. In this embodiment, the receiving slot 31 is recessed from the first housing 10 towards the second housing 20. The receiving slot 31 includes a bottom surface 311, two side surfaces 312 perpendicularly extending from the bottom surface 311, and two end surfaces defining two second cutouts 313.

The receiving portion 30 further defines at least one first latching slot 32 and at least one second latching slot 33. In this embodiment, the at least one first latching slot 32 is defined on the two first side surfaces 312. The at least one second latching slot 33 is defined on the bottom surface 312.

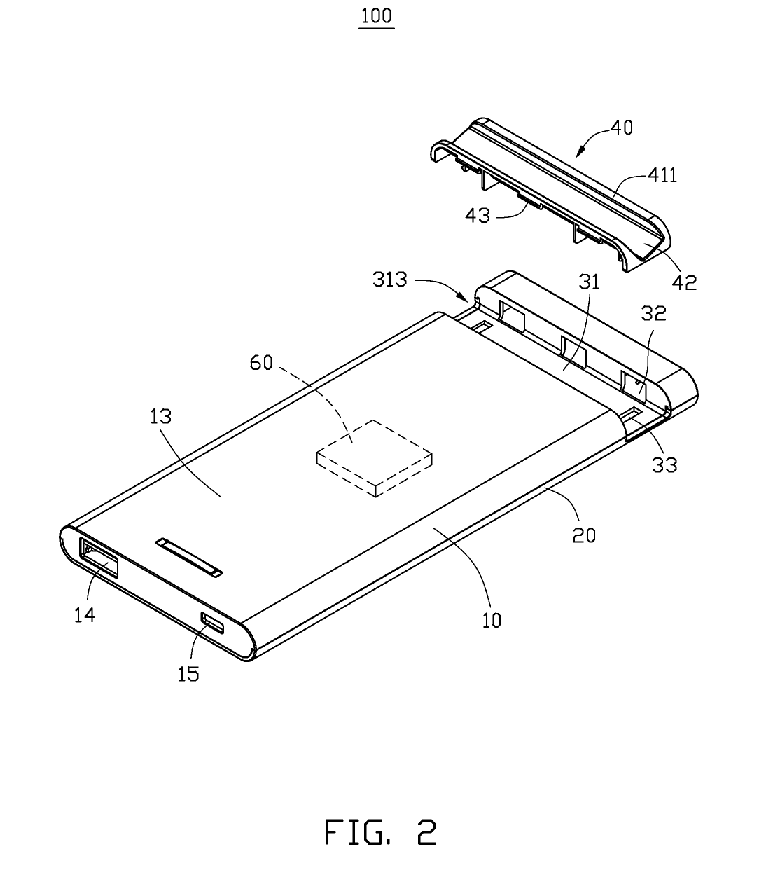

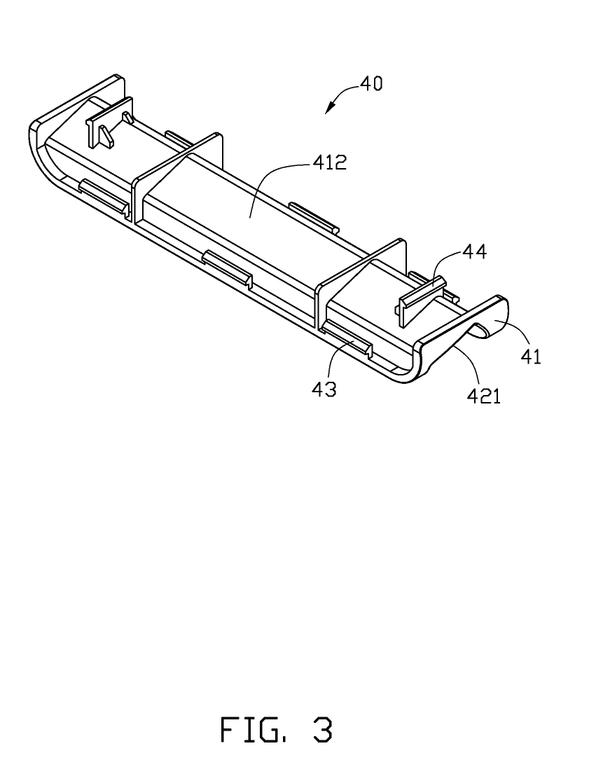

FIGS. 2 and 3 illustrate that the main body 41 further includes at least one first hook 43 and at least one second hook 44. The at least one first hook 43 protrudes from two sides of the interior surface 412. The at least one second hook 44 protrudes from a middle portion of the interior surface 412, positioned between the at least one first hook 43, and is adjacent to the end walls. In this embodiment, there are six first hooks 43 protruding from the sides of the interior surface 412 and two second hooks 44 protruding from a middle portion of the interior surface 412. The at least one first hook 43 is configured to be clasped in and secured in the at least one first latching slot 32. The at least one second hook 44 is configured to be clasped in and secured in the at least one second latching slot 33

As illustrated, the first housing 10 includes a mounting surface 13 opposite to the second housing 20. The receiving slot 31 is defined on the mounting surface 13.

When the main body 41 is assembled in the receiving slot 31, the exterior surface 411 is coplanar with the mounting surface 13 and an included angle is defined between the inclined surface 421 and the mounting surface 13.

FIG. 2 also illustrates a power supply module 60 of the portable power source 100. The power supply module 60 is positioned in the housing 50. As illustrated, a discharging interface 14 and a charging interface 15 are defined on an end of the first housing 10. Thereby, the power module 60 can provide power to the electronic device 200 by the discharging interface 14 and can be charged by the charging interface 15. In this embodiment, both the discharging interface 14 and the charging interface 15 are universal serial bus (USB) interfaces.

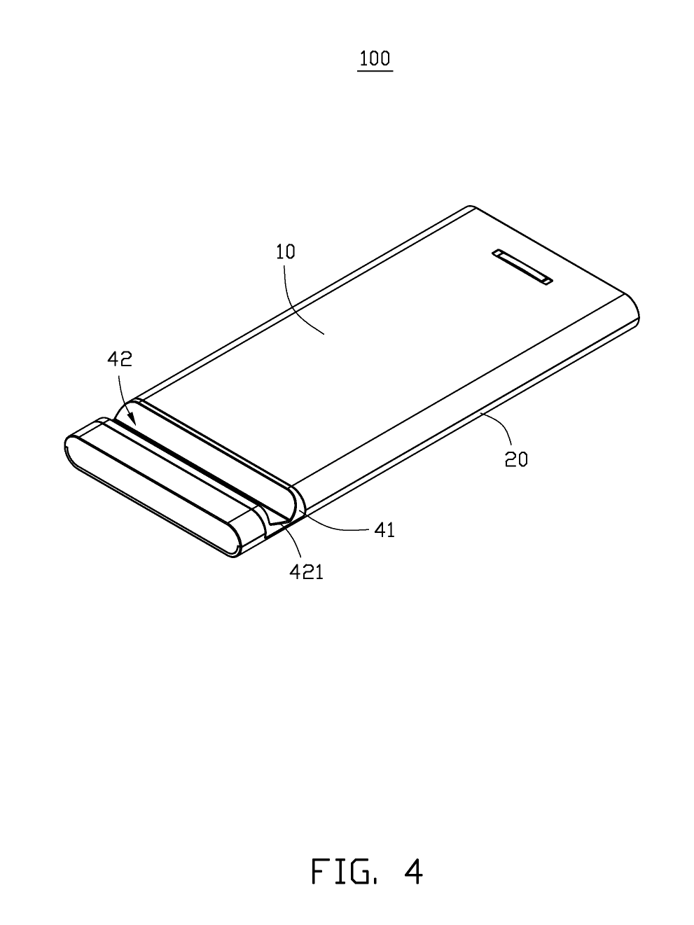

FIG. 4 illustrates an assembled view of the portable power source 100. As illustrated, the first hooks 43 are received in the first latching slot 32. The second hooks 44 are received in the second latching slot 33. Then, the support member 40 is assembled in the receiving slot 31.

FIG. 5 illustrates the electronic device 200 assembled in the notch 42 and latched by the inclined surface 421. Thus, the electronic device 200 can be supported at a desired angle to make it more comfortable for viewing a display or otherwise utilizing the electronic device 200.

The embodiments shown and described above are only examples. Many details are often found in the art. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A portable power source for providing power to an electronic device, the portable power source comprising:
a housing having a power supply module; and
a support member comprising a main body detachably mounted in the housing;
wherein a notch is defined on the main body to latch and support the electronic device.

2. The portable power source of claim 1, wherein the notch forms an inclined surface shaped for receiving and supporting the electronic device in a desired angle, two opposite sidewalls extending from the inclined surface, and two opposite end sidewalls defining two first cutouts.

3. The portable power source of claim 1, further comprising a receiving portion formed on the housing, wherein the receiving portion defines a receiving slot to receive the support member.

4. The portable power source of claim 3, wherein the main body further comprises at least one first hook and at least one second hook, the receiving portion further defines at least one first latching slot to clasp and secure the at least one first hook and at least one second latching slot to clasp and secure the at least one second hook.

5. The portable power source of claim 4, wherein the main body comprises an exterior surface and an interior surface opposite to the exterior surface, the notch is recessed from the exterior surface toward the interior surface, the at least one first hook is protruded on two sides of the interior surface, the at least one second hook is protruded on a middle portion of the interior surface.

6. The portable power source of claim 5, wherein the receiving slot forms a bottom surface, two opposite side surfaces perpendicularly extending from the bottom surface, and two opposite end surfaces defining two second cutouts, the at least one first latching slot is defined on the two opposite side surfaces, the at least one second latching slot is defined on the bottom surface.

7. The portable power source of claim 5, wherein the housing comprises a first housing and a second housing assembled on the first housing, the receiving slot is recessed from the first housing towards the second housing.

8. The portable power source of claim 7, wherein the first housing comprises a mounting surface opposite to the second housing, the receiving slot is defined on the mounting surface, when the main body is assembled in the receiving slot, the exterior surface is coplanar with the mounting surface and an included angle is defined between the inclined surface and the mounting surface.

9. The portable power source of claim 7, wherein a discharging interface and a charging interface are defined on an end of the first housing, the power module provides power to the electronic device by the discharging interface and is charged by the charging interface.

10. A portable power source comprising:
a housing;
a power supply module positioned in the housing to provide power to an electronic device; and
a support member comprising a main body detachably mounted in the housing;
wherein a notch is defined on the main body to latch and support the electronic device.

11. The portable power source of claim 10, wherein the notch forms an inclined surface shaped to support the electronic device in a desired angle, two opposite sidewalls extending from the inclined surface, and two opposite end sidewalls defining two first cutouts.

12. The portable power source of claim 10, further comprising a receiving portion mounted on the housing, wherein the receiving portion defines a receiving slot to receive the support member.

13. The portable power source of claim 12, wherein the main body further comprises at least one first hook and at least one second hook, the receiving portion further defines at least one first latching slot configured to clasp and secure the at least one first hook and at least one second latching slot to clasp and secure the at least one second hook.

14. The portable power source of claim 13, wherein the main body comprises an exterior surface and an interior surface opposite to the exterior surface, the notch is recessed from the exterior surface towards the interior surface, the at least one first hook is protruded on two sides of the interior surface, the at least one second hook is protruded on a middle portion of the interior surface.

15. The portable power source of claim 14, wherein the receiving slot forms a bottom surface, two opposite side surfaces perpendicularly extending from the bottom surface, and two opposite end surfaces defining two second cutouts, the at least one first latching slot is defined on the two opposite side surfaces, the at least one second latching slot is defined on the bottom surface.

16. The portable power source of claim 14, wherein the housing comprises a first housing and a second housing assembled on the first housing, the receiving slot is recessed from the first housing to the second housing.

17. The portable power source of claim 16, wherein the first housing comprises a mounting surface opposite to the second housing, the receiving slot is defined on the mounting surface, when the main body is assembled in the receiving slot, the exterior surface is coplanar with the mounting surface and an included angle is defined between the inclined surface and the mounting surface.

18. The portable power source of claim 16, wherein a discharging interface and a charging interface are defined on an end of the first housing, the power module provides power to the electronic device by the discharging interface and is charged by the charging interface.
